(19) United States
(12) Patent Application Publication
(10) Pub. No.: US 2005/0015689 A1
(43) Pub. Date: Jan. 20, 2005

(54) Electronic component and method for measuring its qualification

(76) Inventors: Friedrich Eppensteiner, A-Wien (AU); Majid Ghameshlu, A-Wien (AU); Karlheinz Krause, Planegg (DE)

Correspondence Address: Siemens Corporation;Intellectual Property Department, 170 Wood Avenue South, Iselin, NJ, 08830, US

(21) Appl. No.: 10/489,685

(22) PCT Filed: Aug. 30, 2002
(86) PCT No.: PCT/EP02/09689

(30) Foreign Application Priority Data
Sep. 21, 2001 (EP) 01122773.3

(51) Int. Cl. G01R 31/28

(52) U.S. Cl. 714/724

(57) ABSTRACT

The invention relates to an electronic component with an integrated semiconductor circuit that comprises a core with functional flip-flops. A part of the functional flip-flops is linked as input flip-flops with input pins of the component and a part of the functional flip-flops is linked as output flip-flops with output pins of the component. In order to allow for efficient and cost-effective ASIC qualification methods that can be carried out rapidly and that take into consideration the growing complexity of integrated circuits and the rapid development of technology, the invention provides a method and a device wherein the input flip-flops and the output flip-flops are interconnected to a shift register during a qualification measurement of the component.

### CROSS REFERENCE TO RELATED APPLICATIONS

This application is the U.S. National Stage of International Application No. PCT/EP02/09689, filed Aug. 30, 2002 and claims the benefit thereof. The International Application claims the benefits of European application No. 01122773.3 filed Sep. 21, 2001, both applications are incorporated by reference herein in their entirety.

### FIELD OF INVENTION

The invention relates to an electronic component with integrated semiconductor circuit that comprises a core containing functional flip-flops, some of the functional flip-flops being connected as input FFs to input pins of the component, and some of the functional flip-flops being connected as output FFs to output pins of the component, as well as a method for its qualification testing.

### BACKGROUND OF INVENTION

Electrical components of this type are often designed as Application Specific Integrated Circuits (ASICs), which undergo extensive qualification procedures after fabrication. ASICs are a collection of circuits having simple functions, such as flip-flops, inverters, NANDs and NORs, and of more complex structures such as memory arrays, adders, counters and phase locked loops. The various circuits are combined in an ASIC in order to implement a specific application. ASICs are used in numerous products, for instance consumer products such as video games, digital cameras, in vehicles and PCs and also in high-end technology products such as workstations and supercomputers.

Known ASIC architectures comprise an ASIC are containing the various circuit elements making up the function of the ASIC. The ASIC core receives the inputs to be processed from input drivers. After processing by the ASIC core, the output data is output via output drivers.

Various “Design for Test” (DFT) techniques are known for testing the functionality of the ASIC. The advantage of DFT techniques is that circuit elements can be inserted back at the chip design stage, which enables later scanbased testing and reduces the number of test points required on the ASIC board while also getting around the problem of unavailable access points.

Large numbers of test vectors are created in known qualification methods or test methods. These test vectors are then input into an ASIC, the aim being to drive certain outputs of the ASIC in order to change the logical state. When the output state changes, the “clock-to-output delay” can be measured, giving the delay between the supplied clocking pulse and the output appearing at the output. For the input areas of an ASIC, qualification methods are used to determine any timing violation that may exist, e.g. violation of the SETUP and HOLD time (see below), and to signal it at the output of the ASIC.

For the output of a flip-flop to be determinate, i.e. not metastable, the inputs to the flip-flop must lie within the SETUP and HOLD time specification for the flip-flop. The SETUP time is the time period prior to the rising edge of the synchronization clock. The HOLD time refers to the time period after the rising edge of the synchronization clock. If the SETUP and HOLD timing criteria of the flip-flop are not met, the output of the flip-flop is not definitely guaranteed. Thus it is extremely important to find the SETUP and HOLD time accurately.

Considerable amounts of time are involved in creating test vectors for qualification methods described above, because some of the test vectors are generated by hand. In addition, it is necessary to know the function of the ASIC core.

Furthermore, the requirements of the test setup must be met, i.e. it might be necessary to stop the test run in order to reload the test vectors because of limited memory depth.

Factors such as high pin count, complexity or logic depth, internal phase locked loops (PLLS) and logic power-up sequences of the ASIC also present problems for the test methods used for qualification of the ASIC. These factors will present even greater difficulties for ASIC qualification in the future.

### SUMMARY OF INVENTION

It is thus the object of the invention stated in claim 1 to create an electronic component and demonstrate a qualification method that in each case provide an efficient, cost-effective and quick to perform ASIC qualification method, while at the same time taking into account the ever increasing complexity of integrated circuits and the accelerating development pace of technology.

This object is achieved by an electronic component as claimed in claim 1, in which the input FFs and the output FFs can be connected together into a shift register during a qualification test of the component.

This results in the following advantages:
Only relatively short test vectors need to be used for the timing measurement.
Short test times are obtained irrespective of the logic depth of the ASIC under test.
The test vectors can be generated automatically from a database similar to the Boundary Scan Description Language file (BDSL File).
Test teams need to get far less involved than before in the function of the ASIC.

According to another advantageous embodiment of the present invention, the input FFs and the output FFs each have a switching element at their inputs, and are connected together by means of these under control from a controller central to all the switching elements. This reduces considerably the time involved in preparing timing measurements on the ASIC.

In a particularly advantageous embodiment, the qualification test is a setup and/or a hold measurement at the input FFs, by means of which the timing measurements can be made without needing to put the central core into operation, and specific inputs and outputs of the integrated circuit are measured using test vectors irrespective of the logic depth in order to be able to make a setup and hold time measurement at the inputs.

In a further advantageous embodiment, the qualification test is a clock-to-output time measurement at the output FFs and/or the outputs of the component, by means of which the timing measurements can be made without needing to put the central core into operation, and specific outputs of the integrated circuit are measured using test vectors irrespective of the logic depth in order to be able to find the clock-to-output delay at the outputs.

In another preferred exemplary embodiment of the invention, the qualification test is an enable-to-output time measurement at the output FFs (8) and/or the outputs of the component (1), by means of which the switching speed of the tristate buffers can be measured.

In another advantageous embodiment, the switching elements are multiplexers, which means that only a small amount of overhead is required in the hardware.

In another advantageous exemplary embodiment, during the qualification test, the respective switching elements connect the output of one input FF or output FF to the input of an adjacent input FF or output FF respectively, in order to produce the shift register in a particularly simple way.

In another advantageous exemplary embodiment, all input and output FFs receive the same clock via a clock tree during the qualification test. Thus a real clock is present during the timing measurements, and the clock tree relevant to the test and the PLLs are included in the timing measurements.

In another advantageous exemplary embodiment, the input and/or output FFs receive a different clock via a clock tree in order to provide qualification tests for an ASIC having different clock domains.

In a particularly advantageous exemplary embodiment, the controller has a first pin for controlling the switching elements, a second pin for controlling the unidirectional output buffers and a third pin for controlling the bidirectional output buffers, in order to provide the shift register and the control of the output buffers during the qualification test separately or in addition to the control from other test methods such as the production test, or a control from the core itself.

In an alternative advantageous exemplary embodiment, the controller has a multiplicity of gates in order to provide, during the qualification method according to the invention, masking of controls from other test procedures, such as the production test, or of a control from the core itself.

In achieving the object according to the invention by providing a method for qualification testing of an electrical component as claimed in claim 13, in which the input FFs and output FFS are connected together into a shift register during a qualification test of the component, the same advantages result as for the device described above.

An exemplary embodiment of the method according to the invention, in which the test data is input in parallel to the input FFS via inputs of the component, and then the controller connects together the input FFs and the output FFs into the shift register, whereby the test data passes serially through the shift register and is read out via one output, results in the additional advantage that timing measurements in the input area can be performed without needing to put the central core into operation.

In another exemplary embodiment of the method according to the invention, the setup and hold time is found by varying the timing of the data input to the input FFs relative to the clock and by verifying the test data read out, enabling a precise definition of the setup and hold criteria to be found.

In another additional exemplary embodiment of the method according to the invention, the controller connects the input FFs and the output FFS into a shift register, the test data is input serially into an input FF via an input of the component, the test data reaches the output FFS by passing serially through the shift register, and the clock-to-output times are measured at the relevant outputs of the component during the shifting sequence of the data into the output FFS. This results in the additional advantage that timing measurements can be made in the output area without needing to put the central core into operation.

In a particularly advantageous exemplary embodiment of the method according to the invention, the test data is input in parallel into the input FFs via the inputs of the component, the controller then connects the input FFs and the output FFs into a shift register, the test data reaches the output FFs by passing serially through the shift register, and the clock-to-output times is measured at the relevant outputs of the component during the shifting sequence of the data into the output FFs. This allows a timing measurement to be made particularly quickly in the output area of the ASIC without needing to put the central core into operation.

In another advantageous exemplary embodiment of the method according to the invention, a tristate buffer is controlled by a flip-flop (8d) of the shift register during the enable-to-output time measurement in the output area, the test vector data input serially into the shift register being used for the control. This enables an enable-to-output time measurement that is particularly simple to implement.

### BRIEF DESCRIPTION OF THE DRAWING

An exemplary embodiment of the invention is shown in the drawing and is described in more detail below. The single figure of the application shows a schematic diagram of an electronic component according to the present invention.

### DETAILED DESCRIPTION OF INVENTION

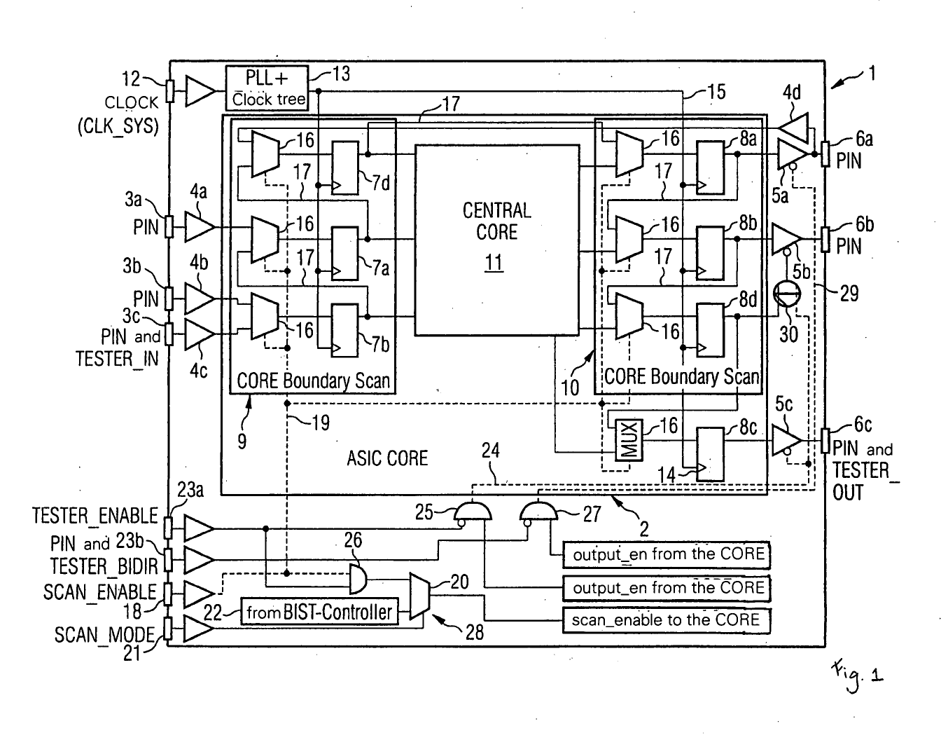

FIG. 1 shows an electronic component, more precisely an Application Specific Integrated Circuit (ASIC) 1 containing an integrated circuit (IC). The IC comprises an ASIC core 2 containing circuit elements such as flip-flops, inverters, NANDs and NORs etc. The arrangement of the circuit elements in the ASIC core 2 provides the specific function of the ASIC 1.

The data to be processed by the ASIC core 2 is input to the ASIC core 2 in parallel via input pins 3a, 3b, 3c and respective series-connected input buffers 4a, 4b, 4c, 4d.

After processing by the ASIC core 2, the processed data is output in parallel via unidirectional tristate buffers 5a, 5b, 5c and respective output pins 6a, 6b and 6c. The tristate output buffers 5a, 5b, 5c can assume the logic states 1 and 0 and a high impedance state Z. In the preferred exemplary embodiment of the present invention, at least one pin 6a is bidirectional, i.e. the pin 6a can be used as an input pin via the input buffer 4d by switching of the tristate buffer 5a into the Z state.

In the ASIC core 2 there are corresponding input flip-flops (input FFs) 7a, 7b, 7d and corresponding output flip-flops (output FFs) 8a, 8b, 8c, 8d for the respective input and output pins 3, 6. The input FFs 7a, 7b, 7d are arranged in at least one input block 9, and the output FFs 8a, 8b, 8d are arranged in at least one output block 10. The ASIC core 2 is thus divided into at least three blocks: the input block 9, the output block 10 and a central core 11. The input block 9 and the output block 10 together form the part of the core 2 referred to as the core boundary.

The circuit elements of the input block 9, the output block 10 and the central core 11 together provide the function of the IC of the ASIC 1. The circuit elements are functional flip-flops (FF) and other functional elements such as inverters, NANDs and NORs etc. The term “functional” is used below to refer to flip-flops or other circuit elements that are only needed for operating the ASIC 1 and for implementing its application-specific function. Such flip-flops or circuit elements that are additionally provided e.g. solely and exclusively for performing test procedures are not covered by this term.

In normal operation of the ASIC 1, the data is input via the input pins 3, and clocked in parallel into the input FFs 7a, 7b, 7d of the input block 9. The data is then transferred in parallel into the central core 11 and processed further. After processing in the central core 11, the data is passed in parallel into the output block 10 where the data is clocked into the output FFs 8a, 8b, 8d and transferred to the output pins 6a, 6b and 6c.

The ASIC 1 has a clock input 12 that clocks the ASIC core 2 via a clock tree 13. The central core 11 and the blocks 9,10 are clocked by using suitable phase locked loops (PLLs) or delay elements (clock input for central core not shown). Each input FF 7a, 7b, 7d and each output FF 8a, 8b, 8d is clocked via clock pins 14 and clock lines 15.

To perform a timing measurement in the input areas and the output areas of the ASIC 1, the input FFs 7a, 7b, 7d are configured with the output FFs 8a, 8b, 8d into a shift register. This is made possible by the series connection of multiplexers 16 to the respective input of an input FF or output FF 7,8. In normal operation of the ASIC 1, the multiplexer 16 switches the inputs from the input pins 3a, 3b, 3c and the outputs from the central core 11 into the input and output FFs 7,8 respectively.

During the ASIC timing measurement, the multiplexers 16 connect the input FFs and output FFs together via lines 17 into a shift register, or more precisely a scan chain (Core Boundary Scan). The chain starts at the input pin 3c, which becomes the input pin TESTER_IN for the test procedure, and ends at the last output FF 8c of an output 6c that doubles as TESTER_OUT.

The multiplexers 16 may already be present for performing the production test along a scan path. In the production test, the functionality of circuit elements in the ASIC core 2 is tested along scan paths or test paths.

The ASIC 1 is switched into the shift mode in the same way as for the production test via a SCAN_ENABLE pin 18 that forms part of a test controller 28. The controller 28, also referred to as a combinatorial device, controls switching elements of the ASIC core 2 and the unidirectional and bidirectional buffers 5a, 5b and 5c when qualification procedures are being performed on the ASIC.

When the shift register is meant to be formed, the multiplexers 16 are controlled by a signal applied to the SCAN_ENABLE pin 18 via scan lines 19. Since the SCAN_ENABLE pin is also used for the production test, signals applied to the pin 18 are also fed to other sections (not shown) of the ASIC core 2 via a multiplexer 20 of the controller 28, said multiplexer being controlled by a scan-mode pin 21 assigned to the controller 28. This is done in order to connect “scan paths”, or test paths, for the production test in the core 2. It would also be possible, however, to input control data from a built-in self-test controller (BIST controller) 21 into the core 2 via the multiplexer 20.

The controller 28 has a TESTER_ENABLE pin 23a for controlling the unidirectional tristate output buffers 5a, 5b, 5c. The signal from the TESTER_ENABLE pin 23a is input with any control signals present from the core into a first gate 25 of the controller 28. In the preferred exemplary embodiment, the first gate 25 is an AND gate, with the signal from the TESTER_ENABLE pin 23a inverted at the input to the AND gate 25. The output of the first gate 25 is taken via a control line 24 to the tristate output buffers 5 and controls their state. At the same time, the signal from the TESTER_ENABLE pin 23a is fed via an additional, second gate 26 of the controller 28 with the signal from the SCAN_ENABLE pin 18 into the multiplexer 20, and hence into the ASIC core 2. The second gate 26 is again an AND gate in the preferred exemplary embodiment. This enables masking, that is blocking, of the signal from the SCAN_ENABLE pin 18 to the ASIC core 2 by means of the TESTER_ENABLE pin 23.

During the qualification test of the present invention, the unidirectional ASIC outputs are enabled. In order to prevent the SCAN_ENABLE signal from the pin 18 to the ASIC core 2 having any effect during the qualification test, whether from PLLs or delay elements, the SCAN_ENABLE signal to the ASIC core 2 is blocked during the qualification test of the present invention, as explained above.

A pin TESTER_BIDIR 23b is used as part of the controller 28 to control the at least one bidirectional pin 6a. A signal at this pin 23b is used to control whether the bidirectional pin 6a is used as input or output pin. In a similar way to the TESTER_ENABLE pin 23a, the signal from the TESTER_BIDIR pin 23b is taken to a third gate 27 with any control signals from the core 2 that may be present. In the preferred exemplary embodiment, the third gate 27 is an AND gate, and in a similar way to the first gate 25, the signal from the TESTER_BIDIR pin 23b is inverted at the input to the gate. The output of the third gate 27 controls the state of the bidirectional tristate output buffer 5a via the control line 29.

An explanation is given below as to how timing measurements, or what is known as a core boundary scan, are made on the input areas and output areas of the ASIC 1 by using the ASIC 1 described above.

A) Measuring the Clock-To-Output Time at the Output:

In order to measure the clock-to-output time, which is also known as the clock-to-output delay, the chain of input FFs 7a, 7b, 7d with the output FFs 8a, 8b, 8d, 8c are brought into the shift mode by means of the SCAN_ENABLE pin 18. The test vector, or the test pattern, for the outputs is input serially via the TESTER_IN pin 3c. The at least one bidirectional pin 6a has been switched into the output mode via the TESTER_BIDIR pin 23b. The clock-to-output time can be measured at the outputs during the serial input sequence of the test vector, e.g. a 0101 pattern. The measured times correspond to those when the ASIC 1 is in normal operation.

Thus, the test vector data is input serially at the input pin 3c to the scan chain, or more precisely the shift register, and is analyzed in parallel at the output. It should be mentioned that a dedicated pin 3c is not essential for the input, because certain inputs can be used in more than one way.

B) Measurement of the Switching Speed:

The measurement of the switching speed of the tristate buffer 5b of the at least one unidirectional pin 6b from Z to 1, from Z to 0, from 0 to Z and from 1 to Z is provided by an additionally implemented flip-flop (FF) 8d in the shift register. Control is effected via the test vector data input serially at the input pin 3c. Control signals from the flit flop 8d or control signals from the gate 25 of the controller 28 are fed to the tristate buffer 5b via a gate 30, which in the preferred exemplary embodiment is an OR gate.

The same effect can also be achieved for bidirectional pins by the measure described.

C) Measurement of SETUP and HOLD Times at the Inputs:

When finding the SETUP and HOLD times, the at least one bidirectional pin 6a is switched to input via the TESTER_BIDIR pin 23b. The input FFs 7a, 7b, 7d are in normal operation, i.e. operating in parallel. At the ASIC 1, the test vector pattern is applied to all input pins 3a, 3b, 3c for one clock pulse, and once the data has been transferred into the input FFs 7a, 7b, 7d, the shift mode is established via the SCAN_ENABLE pin 18 using the multiplexer 16 and the data is output serially from the ASIC 1 so that the data can be analyzed.

This process is then repeated, but the step of applying the test input pattern to all input pins 3 is varied in time relative to the clock. When the analyzed data contains errors, this is an indicator that the SETUP and HOLD timing criterion for the input FF or input FFs has been violated. Thus the SETUP and HOLD time can be found indirectly, because violation of the timing at the inputs is signaled by erroneous output at the outputs of the ASIC 1.

To sum up, it can be said that the present invention provides an electronic component and a method for an improved timing measurement in integrated circuits. The new component and the new method are based on a small amount of advance hardware design work in the ASIC, generally also referred to as Design for Test (DFT). The method and device described above provide the following advantages:
Only relatively short test vectors need to be used for the timing measurement.
Short test times are obtained irrespective of the logic depth of the ASIC 1 under test.
The test vectors can be generated automatically from a database similar to the Boundary Scan Description Language file (BDSL File).
The timing measurements can be performed without needing to put the central core 11 into operation.
The clock tree 13 relevant to the test and the PLLs are included in the timing measurements, i.e. a real clock is present during the timing measurements.
Test teams need to get far less involved than before in the function of the ASIC 1, thus reducing considerably the preparation time involved in timing measurements.
The hardware overhead is low.

The present invention can also be used in particular in connection with the International Application No. PCT/EP02/09690, filed Aug. 30, 2002, titled “Electronic component”, which is incorporated by reference herein in its entirety.

1-22. (canceled)

23. An electronic component with an integrated semiconductor circuit, comprising:
a core operatively connected to the semiconductor circuit;
a plurality of input flip-flops, connected to input pins of the electronic component;
a plurality of output flip-flops connected to output pins of the electronic component,
wherein the input flip-flops are interconnected to the output flip-flops to provide a shift register during a qualification test of the electronic component.

24. The component as claimed in claim 23, wherein the input flip-flops and the output flip-flops each have a switching element at their inputs, and are connected by the switching element, and are controlled by a controller central to the switching elements.

25. The component as claimed in claim 23, wherein the input flip-flops and the output flip-flops are each connected via input buffers to the input pins or via output buffers to the output pins.

26. The component as claimed in claim 23, wherein the qualification test is a setup and/or hold measurement at the input flip-flops.

27. The component as claimed in claim 23, wherein the qualification test is a clock-to-output time measurement at a output flip-flop and/or an output of the component.

28. The component as claimed in claim 23, wherein the qualification test is an enable-to-output time measurement at a output flip-flop and/or an output of the component.

29. The component as claimed in claim 24, wherein the switching elements are multiplexers.

30. The component as claimed in claim 24, wherein the switching element connects the output of an input flip-flop or output flip-flop to the input of an adjacent input flip-flop or output flip-flop during the qualification test.

31. The component as claimed in claim 23, wherein all input and output flip-flops receive the same clock via a clock tree.

32. The component as claimed in claim 23, wherein the input and/or output flip-flops receive a different clock via a clock tree.

33. The component as claimed in claim 24, wherein the controller comprises:
a first pin for controlling the switching elements;
a second pin for controlling unidirectional output buffers; and
a third pin for controlling bidirectional output buffers.

34. The component as claimed in claim 23, wherein the controller comprises a plurality of gates.

35. A method for qualification testing of an electronic component having an integrated semiconductor circuit, comprising:
providing a core operatively connected to the semiconductor circuit;
providing a plurality of input flip-flops, connected to input pins of the electronic component;
providing a plurality of output flip-flops connected to output pins of the electronic component; and
connecting the input flip-flops and the output flip-flops into a shift register during a qualification test of the component.

36. The method as claimed in claim 35, wherein the input flip-flops and the output flip-flops each have a switching element at their inputs, and are connected by the switching element, and are controlled by a controller central to the switching elements.

37. The method as claimed in claim 35, further comprising:
performing a setup and hold measurement of the input flip-flops as a qualification test.

38. The method as claimed in claim 35, further comprising:
parallelly inputting the test data into the input flip-flops via inputs of the component;
connecting the input flip-flops and the output flip-flops into the shift register by a controller;
adapting test data passes serially through the shift register; and
reading out the test data via an output.

39. The method as claimed in claim 35, wherein the setup and hold time is determined by varying a timing of the data input to the input flip-flops relative to a clock and by verifying a test data read out.

40. The method as claimed in claim 35, wherein a clock-to-output time measurement of the output flip-flops is performed as a qualification test.

41. The method as claimed in claim 35, further comprising:
connecting the input flip-flops and the output flip-flops into a shift register by a controller;
serially shifting a test data into an input flip-flop via an input of the component;
serially passing a test data serially through the shift register;
measuring the clock-to-output times at the outputs of the output flip-flops and/or at the output pins during the shifting of the data into the output flip-flops.

42. The method as claimed in claim 35, further comprising:
parallelly inputting a test data into the input flip-flops via the inputs of the component;
connecting the input flip-flops and the output flip-flops into a shift register by a controller;
adapting the test data to reach the output flip-flops serially by passing through the shift register; and
measuring the clock-to-output times at the relevant outputs of the component during the shifting of the data into the output flip-flops.

43. The method as claimed in claim 35, wherein the qualification test is an enable-to-output time measurement of the output flip-flops.

44. The method as claimed in claim 35, further comprising:
driving a tristate buffer by a flip-flop of a shift register during the enable-to-output time measurement of the output flip-flops, a test vector data serially input into the shift register being used for control.
